(19) United States
(12) Patent Application Publication
(10) Pub. No.: US 2008/0087735 A1
(43) Pub. Date: Apr. 17, 2008

(54) RE-CONFIGURABLE MEMORY CARDS HAVING MULTIPLE APPLICATION-BASED FUNCTIONS, METHODS OF OPERATING AND METHODS OF FORMING THE SAME

(75) Inventor: Jin-Jun Park, Seoul (KR)

Correspondence Address: MYERS BIGEL SIBLEY & SAJOVEC, PO BOX 37428, RALEIGH, NC, 27627, US

(73) Assignee: Samsung Electronic Co., Ltd.

(21) Appl. No.: 11/745,121

(22) Filed: May 7, 2007

(30) Foreign Application Priority Data
Oct. 16, 2006 (KR) 10-2006-0100110

(51) Int. Cl. H05K 5/02

(52) U.S. Cl. 235/492

(57) ABSTRACT

A memory card can include a box-shaped printed circuit board defining at least a partially enclosed interior space. A control chip is in the interior space defined by the box-shaped printed circuit board, where the control chip can be selectively configured according one or more application functions. A memory chip is in the interior space and is electrically coupled to the control chip the memory chip being configured to store data. A contact pad is on the box-shaped printed circuit board outside the interior space, where the contact pad is electrically coupled to the control chip. A converting member is located outside the interior space that is defined by the box-shaped printed circuit board and is electrically coupled to the control chip. The converting member is configured to provide an indication to the control chip to change the application function of the control chip and an interfacing function of the contact pad based on input external to the memory card.

### CROSS-REFERENCE TO RELATED APPLICATION

This application claims priority under 35 USC §119 to Korean Patent Application No. 2006-100110 filed on Oct. 16, 2006, the content of which is incorporated herein by reference in its entirety for all purposes.

### FIELD OF THE INVENTION

The present invention relates generally to the field of electronics, and more particularly, to memory cards and methods of manufacturing the same.

### BACKGROUND

Recently, a digital device such as a computer, a cellular phone, a digital camera, a camcorder, etc., has been rapidly developed. Therefore, a memory card as a storage medium, which is used for a peripheral device of the digital device, has also been quickly improved. Particularly, a memory card can have gigabytes of storage capacity. Examples of a conventional memory card are disclosed in Korean Patent Laid-Open Publication Nos. 2006-81703 and 2006-64291.

However, a size, the number of contact pads, etc., of the memory card may vary in accordance with kinds of the digital devices such as the computer, the cellular phone, the digital camera, the camcorder, etc. That is, a memory card applicable for the computer, a memory card applicable for the cellular phone, a memory card applicable for the digital camera and a memory card applicable for the camcorder may have different sizes and different numbers of the contact pads.

Since conventional memory cards may not be compatible with the digital device, separate memory cards may be needed for each type digital device.

### SUMMARY

Embodiments according to the invention can provide reconfigurable memory cards having multiple application-based functions, methods of operating, and methods of forming the same. Pursuant to these embodiments, a memory card can include a box-shaped printed circuit board defining at least a partially enclosed interior space. A control chip is in the interior space defined by the box-shaped printed circuit board, where the control chip can be selectively configured according one or more application functions. A memory chip is in the interior space and is electrically coupled to the control chip the memory chip being configured to store data. A contact pad is on the box-shaped printed circuit board outside the interior space, where the contact pad is electrically coupled to the control chip. A converting member is located outside the interior space that is defined by the box-shaped printed circuit board and is electrically coupled to the control chip. The converting member is configured to provide an indication to the control chip to change the application function of the control chip and an interfacing function of the contact pad based on input external to the memory card.

In some embodiments according to the invention, a method of manufacturing a memory card can include preparing a printed circuit board including a contact pad, providing a control chip having convertible functions and a memory chip for storing data onto a surface of the printed circuit board that is opposite to another face of the printed circuit board on which the contact pad is formed, connecting a converting member to the control chip to convert the convertible function of the control chip, the converting member being located outside the interior space defined by the box-shaped printed circuit board, and bending the printed circuit board into a box shape, so that the contact pad and the converting member being are outside the interior space and the control chip and the memory chip are positioned in the interior space.

In some embodiments according to the present invention, a memory card can include a box-shaped printed circuit board defining at least a partially enclosed interior space and a converting member that is located outside the interior space defined by the box-shaped printed circuit board. The converting member can be electrically coupled to a control chip located in the interior space. The converting member can be configured to provide an indication to the control chip to change an application function of the control chip and an interfacing function of the memory card based on input external to the memory card.

In some embodiments according to the present invention, a method of operating a memory card can include operating the memory card according to a first application function, receiving an external input at the memory card, operating the memory card according to a second application function based on the external input, and changing an interface to the memory card based on the external input including changing a function associated with at least one signal received at the memory card via a single contact on the memory card.

### BRIEF DESCRIPTION OF THE DRAWINGS

The above and other features and advantages of the invention will become readily apparent by reference to the following detailed description when considered in conjunction with the accompanying drawings wherein:

FIG. 1 is a plan view illustrating a memory card in accordance with a first example embodiment of the present invention;

FIG. 2 is a cross-sectional view illustrating the memory card in FIG. 1;

FIGS. 3 to 7 are plan views and perspective views illustrating usage examples of the memory card in FIGS. 1 and 2;

FIGS. 8A to 8D are cross-sectional views illustrating methods of manufacturing memory cards according to FIGS. 1 and 2 in some embodiments according to the present invention; and

FIGS. 9A to 9C are cross-sectional views illustrating methods of manufacturing memory cards according to FIGS. 1 and 2 in some embodiments according to the present invention.

### DESCRIPTION OF THE EMBODIMENTS ACCORDING TO THE INVENTION

The present invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

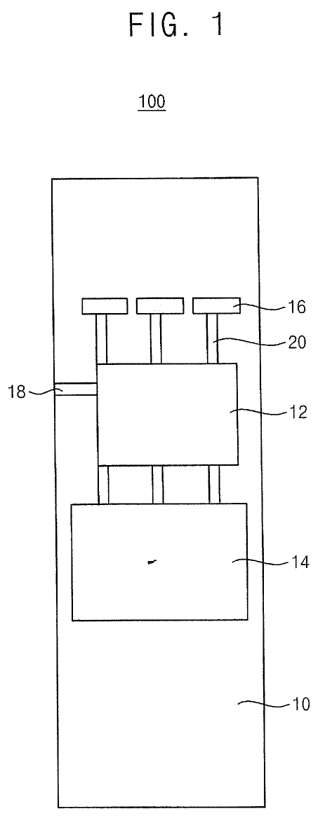

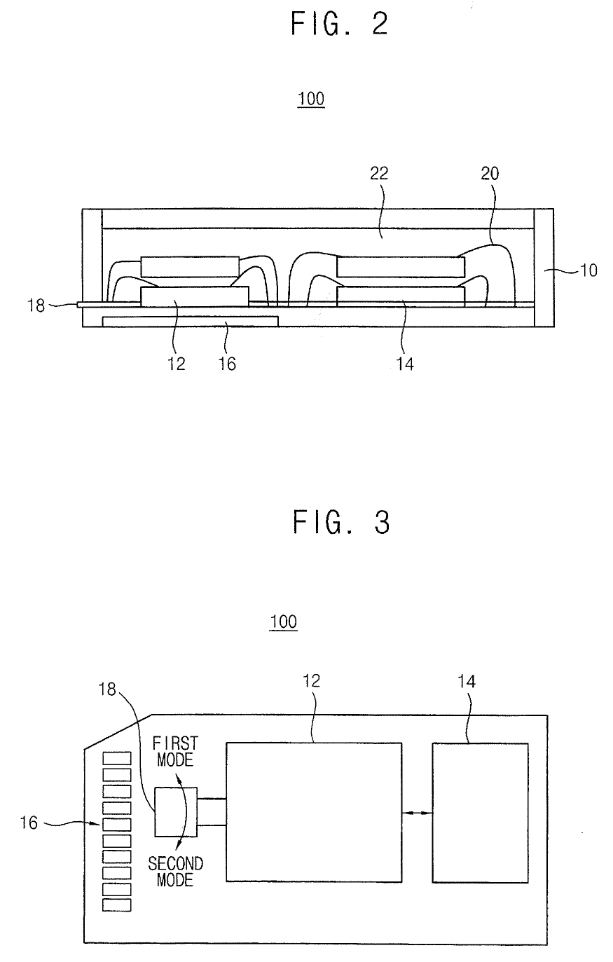

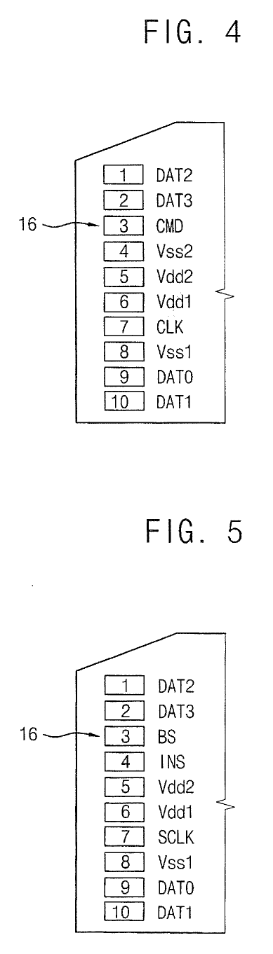

FIG. 1 is a plan view illustrating a memory card in accordance with a first example embodiment of the present invention, FIG. 2 is a cross-sectional view illustrating the memory card in FIG. 1, and FIGS. 3 to 5 are plan views illustrating applications of the memory card in FIGS. 1 and 2.

Referring to FIGS. 1 and 2, a memory card 100 in accordance with this example embodiment includes a printed circuit board (PCB) 10. Particularly, the PCB 10 is bent into a box shape to obtain the memory card 100.

It will be understood that, as used herein, the term “box” means that the PCB is formed to define an interior space in which the components mounted on the present printed circuit board are enclosed. Moreover, some portions of the box shape may be open. For example, the box shape of the PCB may define the interior space so that the chips mounted thereon are completely enclosed. Alternatively, the box shape may be open, such as, at the ends. Accordingly, the term box is not limited to configurations that completely enclosed the interior space in which the components are mounted on the PCB.

A chip module is formed in the box-shaped PCB 10 that is obtained by the bending process. The chip module includes a control chip 12 having convertible functions and a memory chip 14 for storing data. Here, an example of the control chip 12 may include a microprocessor. Further, an example of the memory chip 14 may include a flash memory. Contact pads 16 are formed on the box-shaped memory card 100. The contact pads 16 are electrically connected to the chip module. Further, the memory card 100 includes a converting member 18 connected to the control chip 12. The converting member 18 converts the functions of the control chip 12 by an operation from outside of the PCB 10 and an interfacing function of the contact pads 16. The control chip 12 and the memory chip 14 are electrically connected to each other via a wire 20. Further, the wire 20 is connected between the control chip 12 and the memory chip 14 and, at the same time, the wire 20 is connected to the contact pads 16 on the box-shaped PCB 10. A molding member 22 is formed on the box-shaped PCB 10 to support the control chip 12, the memory chip 14 and the wire 20.

It will be understood that the converting member 18 can be any device which allows an external signal or mechanism to control the function provided by the control chip/interface. For example, the converting member 18 can be a switch, a circuit, a fuse, a jumper, or the like. Furthermore, the converting member may be one-time programmable (such as a laser programmable fuse) or re-programmable (such as a nonvolatile memory or register). Accordingly, the backend process used during the manufacturing of the memory cards would be adapted to select the desired function for the controller chip/interface based on the nature of the converting member 18. For example, if the converting member 18 is a laser programmable fuse, a backend process used to manufacture the memory card may employ a laser to cut fuses included in the converting member 18.

The control chip 12 controls functions of the PCB 10. In this example embodiment, the number of the control chips 12 may be one or at least two.

When the memory card 100 includes the single control chip 12, the single control chip 12 has various functions. That is, the various functions of the single control chip 12 are compatible with different digital devices. Therefore, when the memory card 100 includes the single control chip 12, the functions of the single control chip 12 are converted to be suitable for the different digital devices by operating the converting member 18.

In contrast, when the memory card 100 includes at least the two control chips 12, each of the two control chips 12 has different functions. That is, each of the functions of the control chips 12 is compatible with different digital devices. In other words, any one of the two control chips 12 has a function suitable for a first digital device, and the remaining control chip 12 has a function suitable for a second digital device. Therefore, when the memory card 100 includes the two single control chips 12, each of the functions of the control chips 12 is converted to be suitable for the different digital devices by operating the converting member 18.

In this example embodiment, there are illustrated the single control chip 12 or the two control chips 12. Alternatively, it is obvious to persons skilled in the art that the memory card 100 may include at least three control chips based on the above illustrations.

Further, when the memory card 100 includes at least two control chips 12, the control chips 12 may be advantageously stacked. The stacked structure of the control chip 12 may increase an integration degree of the memory card 100.

When the converting member 18 converts the functions of the control chip 12, the interfacing function of the contact pads 16 may be simultaneously converted. That is, the converting member 18 converts the interfacing function of the contact pads 16 as well as the functions of the control chip 12. Thus, the functions of the memory card 100 are converted to be suitable for the different digital devices so that the memory card 100 may be readily compatible with the different digital devices.

To increase a storage capacity of the memory chip 14, at least two memory chips 14 may be formed in the PCB 10. When at least two memory chips 14 are formed in the PCB 10, the memory chips 14 may be advantageously stacked, thereby increasing an integration degree of the memory card 100.

In addition, the memory card 100 may further include a driver for driving the memory card 100, an interfacing member for transmitting a signal, etc.

In operation, the memory card may operate according to a first application function, such as an interface and function according to a digital camera. Upon receiving an external input at the memory card at the converting member, the controller circuit and cease operating according to the first application function and subsequently begin operating according to a second application function, such as a MP3 player. Furthermore, the interface to the memory card can be changed from a configuration that accommodates the first application function to a configuration that supports the second application function. For example, the signals provided to the memory card during the first application function can be interpreted according to the first application whereas the signals provided subsequent to the change can be interpreted according to the second application. Accordingly, the signals received at the same contact during different application functions can be interpreted differently.

FIGS. 3 to 7 are plan views and perspective views illustrating usage examples of the memory card in FIGS. 1 and 2. Here, same reference numerals refer to same elements of the memory card 100 in FIGS. 1 and 2.

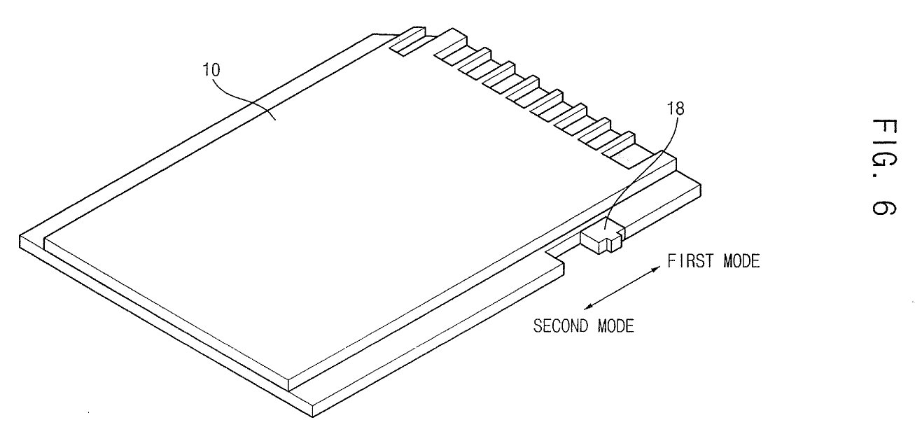

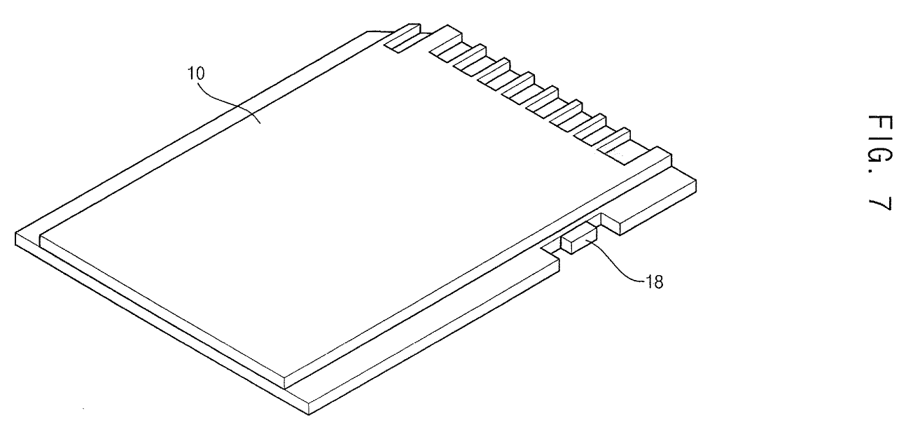

Referring to FIG. 3, the memory card 100 includes a single control chip 12 having a first function and a second function. When the converting member 18 is provided with a first mode, the control chip 12 has the first function. In contrast, when the converting member 18 is provided with a second mode, the control chip 12 has the second function. Further, when the converting member 18 is provided with a first mode, the interfacing function of the contact pads 16 is converted into a mode in FIG. 4. In contrast, when the converting member 18 is provided with a second mode, the interfacing function of the contact pads 16 is converted into a mode in FIG. 5.

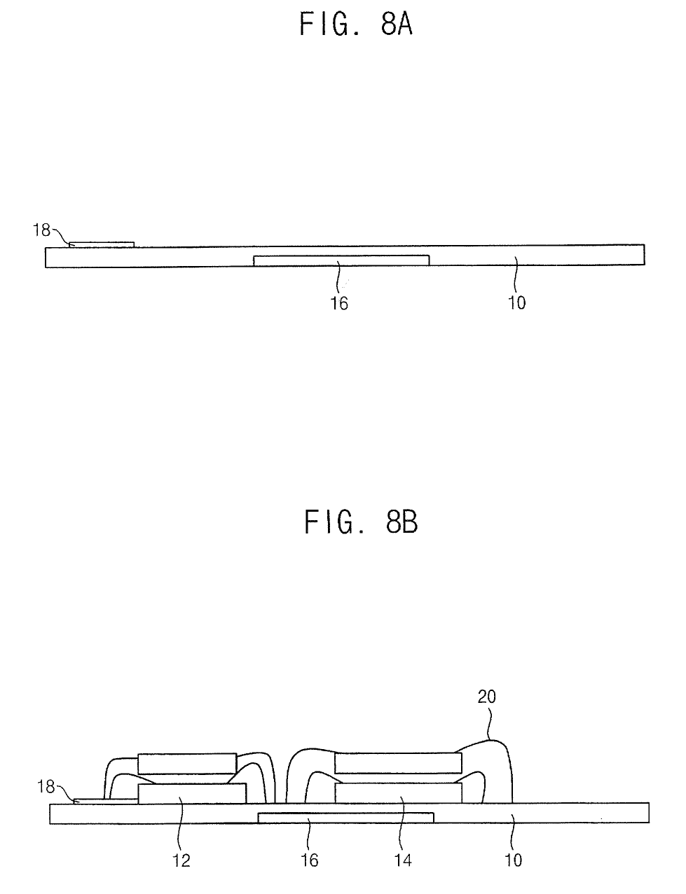

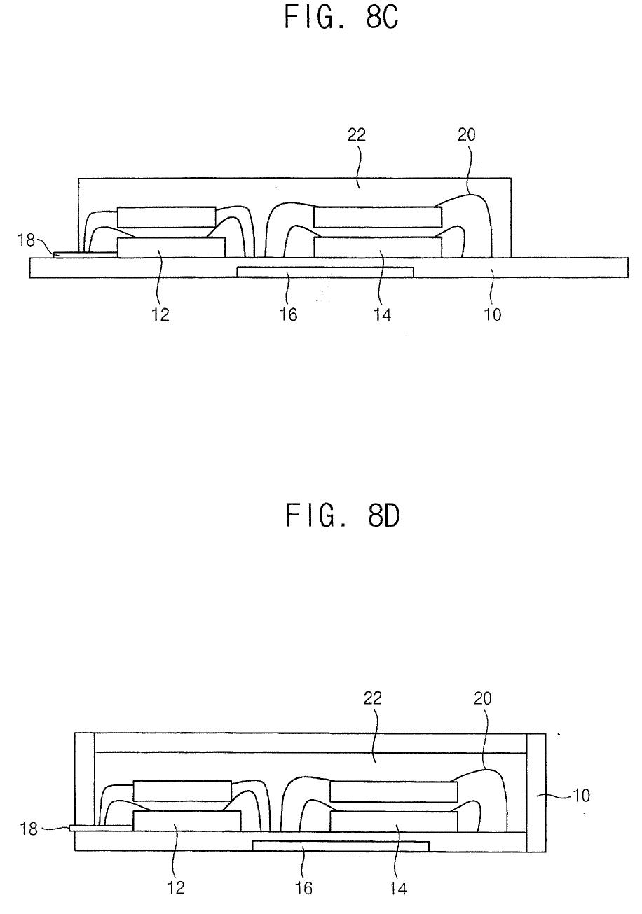

Here, as shown in FIG. 6, the converting member 18 may be provided the first mode or the second mode by a manual operation. Alternatively, as shown in FIG. 7, the converting member 18 may be provided with the first mode or the second mode by an electrical operation.

Accordingly, in the memory card 100, the functions of the control chip 12 are converted into the first function by adjusting the converting member 18 to have the first mode, and the interfacing function of the contact pads 16 is also converted to be suitable for the first function of the control chip 12. Further, the functions of the control chip 12 are converted into the second function by adjusting the converting member 18 to have the second mode, and the interfacing function of the contact pads 16 is also converted to be suitable for the second function of the control chip 12.

For example, when the converting member 18 is provided with the first mode, the functions of the memory card are converted to be suitable for a cellular phone. Further, when the converting member 18 is provided with the second mode, the functions of the memory card are converted to be suitable for a digital camera.

Here, in this example embodiment, the memory card 100 including the single control chip 12 that has the first function and the second function is exemplarily illustrated. Alternatively, the memory card 100 may include a single control chip having first to n-th functions or a plurality of control chips having first to n-th functions, respectively.

The memory card 100 of the present invention may be compatible with the different digital devices based on the above-mentioned memory card and the usage examples of the memory card.

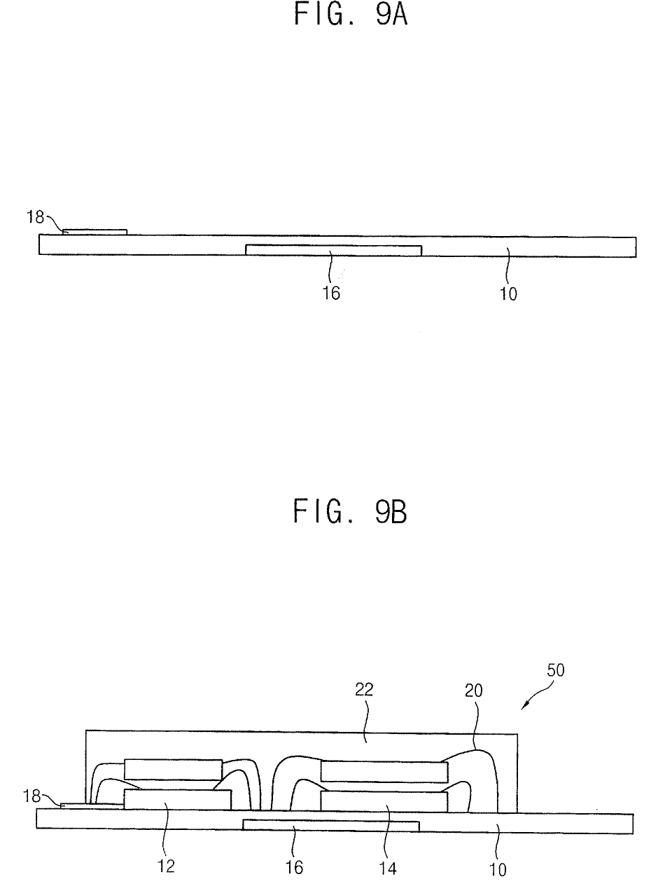

FIGS. 8A to 8D are cross-sectional views illustrating methods of manufacturing the memory card in FIGS. 1 and 2 in some embodiments according to the present invention. Here, same reference numerals refer to same elements of the above-mentioned memory card 100.

Referring to FIG. 8A, the PCB 10 is prepared. Here, the contact pad 16 is formed on a first face of the PCB 10. The converting member 18 is formed on the PCB 10. When the PCB 10 is bent into the box shape, the contact pad 16 is positioned on a second face of the box-shaped PCB 10 opposite to the first face. Further, the contact pad 16 may be readily formed in accordance with a design of the PCB 10.

As used herein, the term “bent” includes the application of any force used to provide the shape of the PCB 10 to enclose the components mounted thereon in the box shape described above. For example, in some embodiments according to the invention, the PCB 10 may be molded, deformed, molded, assembled, stamped or any other type of operation known to those skilled in the art used to form a box shape as described herein.

Referring to FIG. 8B, the chip module is formed on the second face of the PCB 10. That is, the control chip 12 having convertible functions and the memory chip 14 for storing data are formed on the second face of the PCB 10. Further, when the control chip 12 and the memory chip 14 have at least two, respectively, the control chips 12 and the memory chips 14 may be stacked according to an integration degree of the memory chard 100.

The control chip 12 and the memory chip 14 are then electrically connected to each other using a wire 20. Further, the wire 20 is electrically connected to the contact pad 16. The converting member 18 is electrically connected to the control chip 12. Here, when the PCB 10 is bent into the box shape, the converting member is located at an outside of the PCB for allowing the converting member 18 to be handled by the outside operation.

Referring to FIG. 8C, after the control chip 12, the memory chip 14 and the wire 20 are formed, the molding member 22 covers the control chip 12, the memory chip 14 and the wire 20 to firmly fix the control chip 12, the memory chip 14 and the wire 20.

Referring to FIG. 8D, the PCB 10 is bent into the box shape, thereby completing the memory card 100, which includes the contact pad 16 on the box-shaped PCB 10 and the chip module in the box-shaped PCB 10.

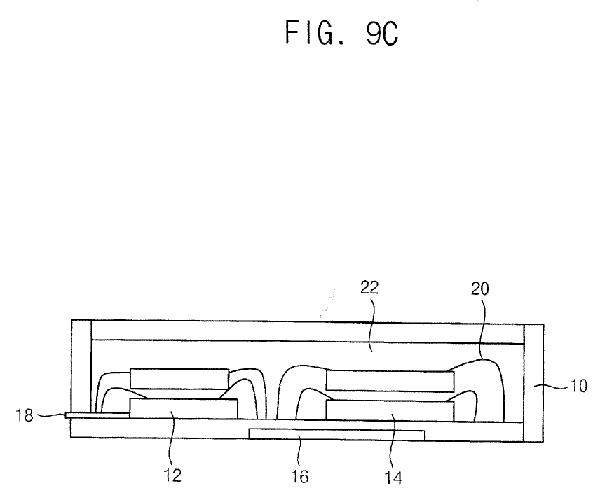

FIGS. 9A to 9C are cross-sectional views illustrating a method of manufacturing a memory card in accordance with a third example embodiment of the present invention. Here, the same reference numerals refer to same elements of the above-mentioned memory card 100.

Referring to FIG. 9A, the PCB 10 is prepared. Here, the contact pad 16 is formed on a first face of the PCB 10. The converting member 18 is formed on the PCB 10. When the PCB 10 is bent into the box shape, the contact pad 16 is positioned on a second face of the box-shaped PCB 10 opposite to the first face.

Referring to FIG. 9B, a package member 50 is placed on the second face of the PCB 10. The converting member 18 is electrically connected to the control chip 12. Here, the control chip 12, the memory chip 14 and the wire 20 are molded in the package member 50. That is, after preparing the PCB 10, the package member 50 is located on the PCB 10.

Referring to FIG. 9C, the PCB 10 is bent into the box shape, thereby completing the memory card 100. In this example embodiment, the memory card 100 is manufactured using the package member 50.

According to the present invention, since the functions of the memory chip and the interfacing function of the contact pad in the memory card may be properly converted or selected, the memory card may be readily compatible with different digital devices such as a computer, a cellular phone, etc.

Moreover, because the converting member can be accessed from outside the box shaped PCB, the memory chip and interfacing function of the memory card can be programmed after the manufacturing processes are otherwise complete. Accordingly, as memory cards are completed, the memory cards can be programmed for the desired application. For example, as memory cards come off the manufacturing line, some may be programmed to operate with a digital camera, others may be programmed to operate with an MP3 player, still other memory cards may be programmed to operate with other types of electronic devices.

In other embodiments according to the invention, the memory cards can be reconfigured in-circuit or while otherwise installed in a device. For example, in some consumer devices that may support multiple functions (such as a camera that can play MP3s), the memory card function can be changed from a first function that supports MP3 to a second function that supports digital camera operations.

Having described embodiments of the present invention, it is noted that modifications and variations can be made by persons skilled in the art in light of the above teachings. It is therefore to be understood that changes may be made in the particular embodiment of the present invention disclosed which is within the scope and the spirit of the invention outlined by the appended claims.

What is claimed is:

1. A memory card comprising:
a box-shaped printed circuit board defining at least a partially enclosed interior space;
a control chip in the interior space defined by the box-shaped printed circuit board, wherein the control chip is selectively configured according one or more application functions;
a memory chip, in the interior space, electrically coupled to the control chip and configured to store data;
a contact pad formed on the box-shaped printed circuit board outside the interior space, the contact pad being electrically coupled to the control chip; and
a converting member located outside the interior space defined by the box-shaped printed circuit board and electrically coupled to the control chip, the converting member configured to provide an indication to the control chip to change the application function of the control chip and an interfacing function of the contact pad based on input external to the memory card.

2. The memory card of claim 1, wherein control chip comprises a single control chip, and the functions of the single control chip are converted to be suitable for the different digital devices responsive to operations of the converting member.

3. The memory card of claim 1, wherein the control chip comprises at least two control chips having respective different functions adapted for different digital devices selected responsive to operations of the converting member.

4. The memory card of claim 1, wherein the memory chip comprises at least two memory chips.

5. The memory card of claim 1, further comprising:
a molding member in the interior space configured to support the control chip and the memory chip.

6. The memory card according to claim 1, wherein the converting member comprises a switch, a circuit, a fuse, and/or a jumper.

7. A method of manufacturing a memory card, comprising:
preparing a printed circuit board including a contact pad;
providing a control chip having convertible functions and a memory chip for storing data onto a surface of the printed circuit board that is opposite to another face of the printed circuit board on which the contact pad is formed;
connecting a converting member to the control chip to convert the convertible function of the control chip, the converting member being located outside the interior space defined by the box-shaped printed circuit board; and
bending the printed circuit board into a box shape, so that the contact pad and the converting member being are outside the interior space and the control chip and the memory chip are positioned in the interior space.

8. The method of claim 7, further comprising:
forming a molding member in the interior space defined by the box-shaped printed circuit board to support the control chip and the memory chip.

9. The method of claim 7, wherein the control chip comprises at least two control chips stacked on each other and having different functions.

10. The method of claim 7, wherein the memory chip comprises at least two memory chips stacked on each other.

11. A memory card comprising:
a box-shaped printed circuit board defining at least a partially enclosed interior space; and
a converting member located outside the interior space defined by the box-shaped printed circuit board and electrically coupled to a control chip in the interior space, the converting member configured to provide an indication to the control chip to change an application function of the control chip and an interfacing function of the memory card based on input external to the memory card.

12. The memory card according to claim 11, wherein the converting member comprises a switch, a circuit, a fuse, and/or a jumper.

13. A method of operating a memory card comprising:
operating the memory card according to a first application function;
receiving an external input at the memory card at a converting member;
operating the memory card according to a second application function based on the external input; and
changing an interface to the memory card based on the external input including changing a function associated with at least one signal received at the memory card via a single contact on the memory card.

14. The method according to claim 13, wherein the converting member comprises a switch, a circuit, a fuse, and/or a jumper.
